(19) United States
(12) Patent Application Publication
(10) Pub. No.: US 2023/0352570 A1
(43) Pub. Date: Nov. 2, 2023

(54) BIPOLAR JUNCTION TRANSISTOR

(71) Applicant: GLOBALFOUNDRIES U.S. Inc., Malta, NY (US)

(72) Inventors: Mark D. Levy, Williston, VT (US); Sarah A. McTaggart, Essex Junction, VT (US); Laura J. Silverstein, Richmond, VT (US); Qizhi Liu, Lexington, MA (US); Jason E. Stephens, Menands, NY (US)

(21) Appl. No.: 17/733,118

(22) Filed: Apr. 29, 2022

(51) Int. Cl. H01L 29/732; H01L 29/66; H01L 29/08; H01L 29/10; H01L 29/45

(52) U.S. Cl. CPC H01L 29/732; H01L 29/66272; H01L 29/0817; H01L 29/0821; H01L 29/1004; H01L 29/456

(57) ABSTRACT

The present disclosure relates to semiconductor structures and, more particularly, to a bipolar junction transistor and methods of manufacture. The structure includes: a collector region; a base region adjacent to the collector region; an emitter region adjacent to the base region; contacts having a first material connecting to the collector region and the base region; and at least one contact having a second material connecting to the emitter region.

### BACKGROUND

The present disclosure relates to semiconductor structures and, more particularly, to a bipolar junction transistor and methods of manufacture.

Bipolar transistors can be vertical transistors or lateral transistors. Lateral bipolar junction transistors may be used in many different applications such as automotive applications. These devices can attain very high Ft (current gain cut-off frequency) and high Fmax (power gain cut off frequency) values compared to CMOS. In advanced nodes, though, as contact size shrinks, emitter resistance (Re) and collector resistance (Rc) increase as does the collector capacitance (Cbc). This negatively impacts Ft/Fmax. A factor that may be contributing to device performance degradation may be self-heating of the devices due to current flow.

### SUMMARY

In an aspect of the disclosure, a structure comprises: a collector region; a base region adjacent to the collector region; an emitter region adjacent to the base region; contacts comprising a first material connecting to the collector region and the base region; and at least one contact comprising a second material connecting to the emitter region.

In an aspect of the disclosure, a structure comprises: a collector region comprising a reach through and sub-collector; a base region above the collector region; an emitter region above the collector region; contacts connecting to the collector region and the base region; and at least one contact connecting to the emitter region and having a higher thermal conductivity than material of the contacts connecting to the collector region and the base region.

In an aspect of the disclosure, a method comprises: forming a collector region; forming a base region adjacent to the collector region; an emitter region adjacent to the base region; forming contacts comprising a first material connecting to the collector region and the base region; and forming at least one contact comprising a second material connecting to the emitter region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a bipolar junction transistor, amongst other features, and respective fabrication processes in accordance with aspects of the present disclosure.

FIG. 2 shows a bipolar junction transistor, amongst other features, and respective fabrication processes in accordance with additional aspects of the present disclosure.

FIGS. 3A-3C show fabrication processes for manufacturing the bipolar junction transistor of FIG. 1 in accordance with aspects of the present disclosure.

### DETAILED DESCRIPTION

The present disclosure relates to semiconductor structures and, more particularly, to a bipolar junction transistor and methods of manufacture. More specifically, the present disclosure relates to a bipolar junction transistor with contacts of dissimilar materials. Advantageously, the use of contacts of dissimilar materials improves heat dissipation of the device with, in turn, improves transistor performance, e.g., approximately an 8% improvement in Ft/Fmax compared to conventional structures in a 25 mA heat source.

In more specific embodiments, the bipolar junction transistor may be an NPN transistor with interconnect structures (e.g., contacts) between the device and backend of the line (BEOL) wiring structures. For example, interconnect structures of a first material may contact the collector region (e.g., reach through extending to a sub-collector region) and base region, and an interconnect structure of a second material may contact the emitter region. In embodiments, the second material has a higher thermal conductivity than the first material. Accordingly, the second material used as the interconnect structure to the emitter region may enhance the thermal dissipation of the transistor through the BEOL wiring layers which, in turn, improves device performance. The interconnect structure to the emitter region may also be wider than the interconnect structures to the collector region and the base region.

The bipolar junction transistor of the present disclosure can be manufactured in several ways using different tools. In general, though, the methodologies and tools are used to form structures with dimensions in the micrometer and nanometer scale. The methodologies, i.e., technologies, employed to manufacture the bipolar junction transistor of the present disclosure have been adopted from integrated circuit (IC) technology. For example, the structures are built on wafers and are realized in films of material patterned by photolithographic processes on the top of a wafer. In particular, the fabrication of the bipolar junction transistor uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

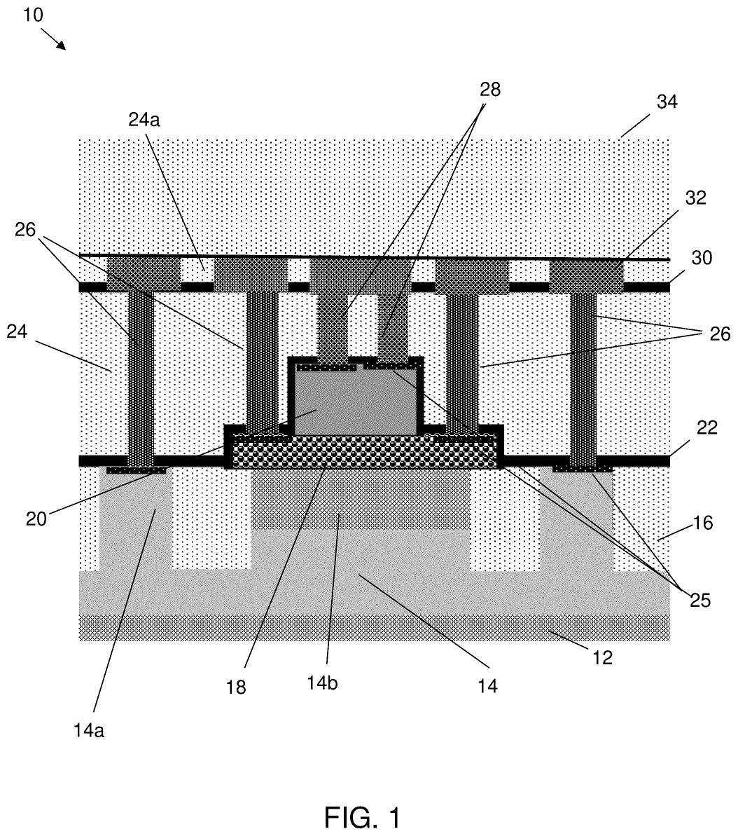

FIG. 1 shows a bipolar junction transistor, amongst other features, and respective fabrication processes in accordance with aspects of the present disclosure. In particular, the bipolar junction transistor 10 includes a semiconductor substrate 12. In embodiments, the semiconductor substrate 12 may be a P-type substrate composed of any suitable material including, but not limited to, Si, SiGe, SiGeC, SiC, GaAs, InAs, InP, and other III/V or II/VI compound semiconductors. In embodiments, the semiconductor substrate 12 may be a bulk substrate or, alternatively, may be semiconductor on insulator (SOI) technologies. The semiconductor substrate 12 may also comprise any suitable crystallographic orientation (e.g., a (100), (110), (111), or (001) crystallographic orientation).

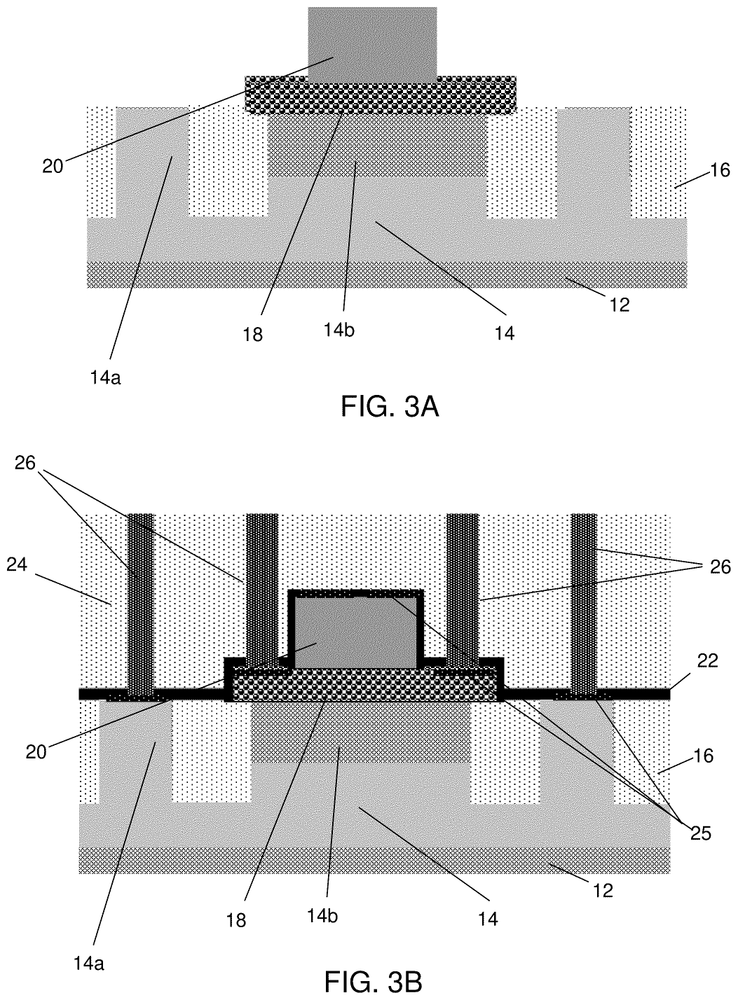

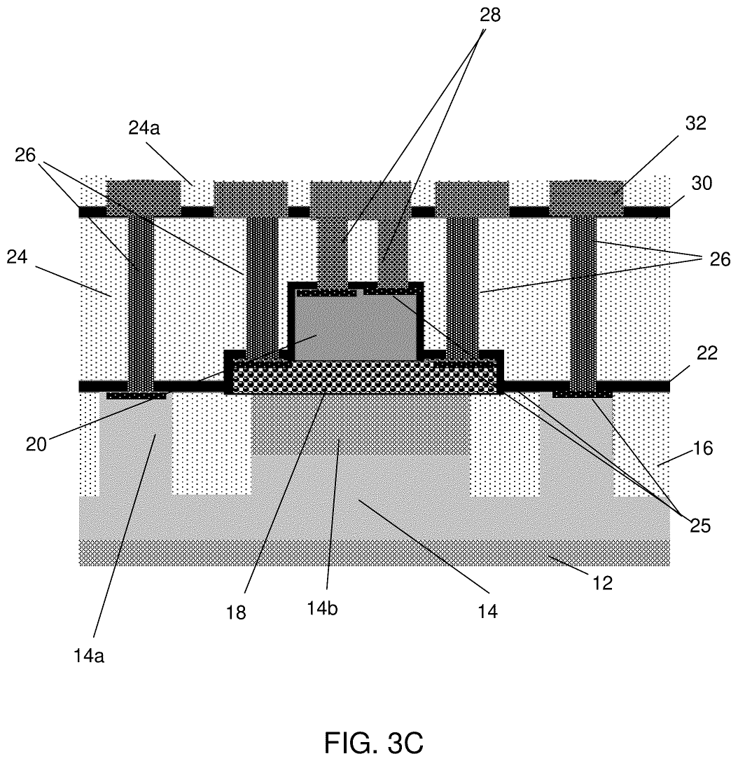

A sub-collector region (e.g., n-well) 14 may be formed in the semiconductor substrate 12. In embodiments, the sub-collector region 14 may be formed by either an epitaxial growth process or an ion implantation process as described in more detail with respect to FIG. 3A. For example, in an epitaxial growth process, semiconductor is selectively grown on the semiconductor substrate 12, followed by additional growth of semiconductor material for an upper portion of the semiconductor substrate 12. The ion implantation process, on the other hand, introduces a concentration of a dopant in the semiconductor substrate 12. The dopant, in either the ion implantation or an in-situ doping processes, may be n-type dopants, e.g., Arsenic (As), Phosphorus (P) and Sb, among other suitable examples, at different concentrations.

A reach through 14a may be formed in the semiconductor substrate 12 and extends to the sub-collector region 14, between shallow trench isolation structures 16. The reach through 14a may also be formed by an ion implantation process with n-type dopants, e.g., Arsenic (As), Phosphorus (P) and Sb, among other suitable examples, at different concentrations. In embodiments, the reach through 14a may be formed prior to the formation of the shallow trench isolation structures 16. As should also be understood by those of skill in the art, a collector region 14b may be provided over the sub-collector region 14.

Still referring to FIG. 1, one or more shallow trench isolation structures 16 may be formed in the semiconductor substrate 12. The one or more shallow trench isolation structures 16 may be formed by conventional lithography, etching and deposition methods known to those of skill in the art and as further described with respect to FIG. 3A.

A base region 18 may be formed on the semiconductor substrate 12. In embodiments, the base region 18 may be a single crystalline semiconductor material with an SiGe material in the active region (over the collector region 14b) and a polysilicon material and SiGe layer in the inactive regions, e.g., over the shallow trench isolation structures 16. In embodiments, the base region 18 may be an intrinsic and extrinsic base region. The base region 18 may be formed by an epitaxial growth process followed by a patterning process as is known in the art.

An emitter region 20 may be formed on the base region 18. In embodiments, the emitter region 20 may comprise polysilicon material formed by a deposition process as is known in the art. The emitter region 20 may be patterned by conventional lithography and etching processes as is known in the art. The emitter region 20 may include sidewall spacers which may be formed by a deposition process of, e.g., nitride and/or oxide, followed by an anisotropic etching process. As shown, the emitter 20 may be the highest feature of the vertical device, i.e., vertical bipolar junction transistor or vertical heterojunction bipolar junction transistor.

In embodiments, an optional liner 22 may be formed over the exposed portions of the semiconductor substrate 12, a top surface of the shallow trench isolation structures 16, the base region 18, and the emitter region 20. In embodiments, the liner 22 may be a nitride material, for example, deposited by a blanket deposition method, e.g., CVD. An interlevel dielectric material 24 may be formed over the liner 22, in addition to over the base region 18 and the emitter region 20. In embodiments, the interlevel dielectric material 24 may be SiO₂ deposited by a CVD process. The interlevel dielectric material 24 may also be subjected to a planarization process, e.g., CMP.

Contacts 26 may be formed in the interlevel dielectric material 24 using a single damascene process, e.g., etching and deposition. In embodiments, the contacts 26 will contact silicide contacts 25 of the semiconductor substrate 12, e.g., reach throughs 14a, and base region 18. The silicide contacts 25 may be formed prior to the deposition of the interlevel dielectric material 24, using conventional silicide processes on exposed semiconductor material, e.g., exposed portions of the semiconductor substrate 12 and base region 18. The contacts 26 can be formed by conventional lithography, etching and deposition methods known to those of skill in the art and as described in further detail with respect to FIG. 3B.

As further shown in FIG. 1, two or more contacts 28 may be formed in the interlevel dielectric material 24 extending to, and contacting, the silicide contacts 25 formed on the emitter region 20. The contacts 28 and wiring structures 32 may be formed by a dual damascene process, as an example.

Prior to forming of the contacts 28 and the wiring structures 32, an optional liner 30 may be formed over the interlevel dielectric material 24, with an additional interlevel dielectric material 24a formed over the liner 30. The liner 30 may be a nitride material and the interlevel dielectric material 24a may be SiO₂ as examples. The liner 30 and the interlevel dielectric material 24a may be deposited by conventional CVD processes. The contacts 28 and the wiring structures 32 may then be formed by lithography, etching and deposition processes as is known in the art and described in further detail with respect to FIG. 3C. The emitter contacts 28 may have a top surface essentially coplanar with the top of the contacts 26. Any residual material on the interlevel dielectric material 24a may be removed by a CMP process, followed by deposition of back end of the line structures, e.g., the interlevel dielectric material 34, etc.

In embodiments, the contacts 28 comprise a different material than the contacts 26. More specifically, the material of the contacts 28 has a higher thermal conductivity than the material of the contacts 26. Illustratively, the contacts 28 may be copper, whereas the contacts 26 may be tungsten. Alternatively, any combination of the materials shown in Table 1 may be used for the contacts 28, 26, with a material of higher thermal conductivity being used for the contacts 28.

TABLE 1

| Contact Material | Thermal Conductivity |
|---|---|
| Copper | 410 W/mk |
| Tungsten | 182 W/mk |
| Cobalt | 104 W/mk |
| P-Silicon | 130 W/mk |

In this way, the contacts 28 will dissipate more heat from the center of the device, e.g., emitter region 20, compared to conventional devices that use a same material for each of the contacts. For example, the copper emitter contacts provide improved thermal conductance and, hence, provides superior control of heating to tungsten contacts.

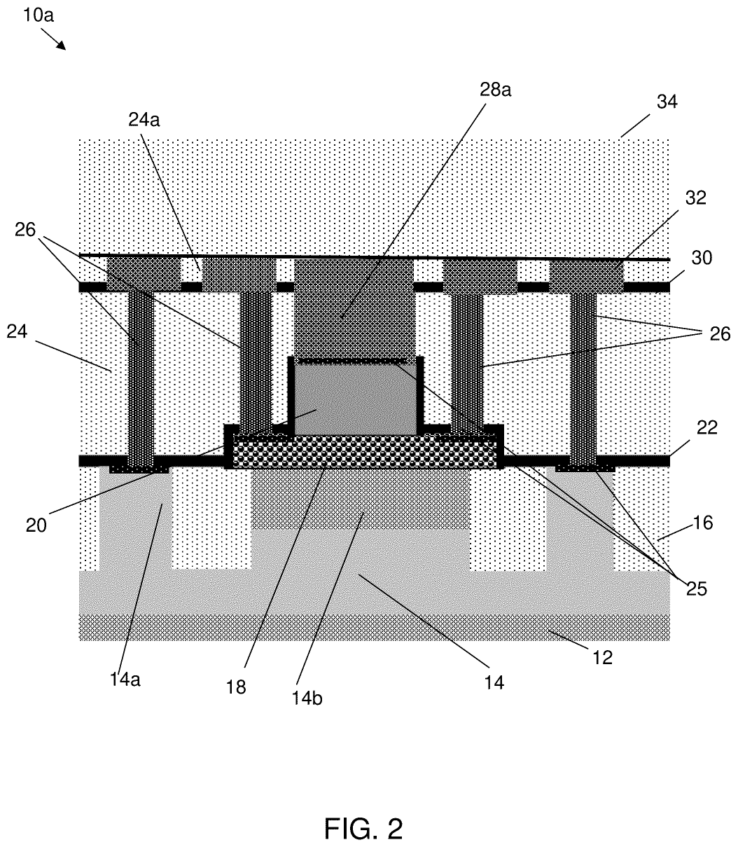

FIG. 2 shows a bipolar junction transistor, amongst other features, and respective fabrication processes in accordance with additional aspects of the present disclosure. In this structure 10a, the emitter region 20 of the bipolar junction transistor 10 includes a single contact 28a spanning an entire emitter opening, e.g., entire width of the emitter region 20. Again, the contact 28a will be of a different material than the contacts 26, with the contact 28a comprising a material of higher thermal conductivity than the material of the contacts 26. The contacts 28a may contact a large range of emitter widths, e.g., from minimum width for a Low Noise Amplifier (e.g., 0.2 μm) to a much wider width (e.g., 1.6 μm) for power amplifiers. In addition, by using a single contact, it is now possible to have less current crowding through contacts, with an improved thermal dissipation for all emitter widths. The remaining features of FIG. 2 are similar to the structure 10 shown in FIG. 1 such that no further explanation is required for a complete understanding of the present disclosure.

FIGS. 3A-3C show fabrication processes for forming the bipolar junction transistor of FIG. 1. FIG. 3A shows a starting structure with standard fabrication processing to form the sub-collector region (e.g., n-well) 14, reach throughs 14a, shallow trench isolation structures 16, base region 18 and emitter region 20. Specifically, starting with the semiconductor substrate 12, either an epitaxial growth process or an ion implantation process may be used to form the sub-collector region (e.g., n-well) 14.

The epitaxial growth process is a selective growth of semiconductor material on the semiconductor substrate 12. In accordance with exemplary embodiments, epitaxy regions include SiGe or Si or, alternatively, III-V compound semiconductor material, combinations thereof, or multi-layers thereof. An n-type impurity may be in-situ doped during the epitaxial process

The ion implantation can be used to form the sub-collector region 14 and the reach throughs 14a. In the ion implantation process, a dopant is introduced at different concentrations in the semiconductor substrate 12 for the sub-collector region 14 and the reach throughs 14a. In embodiments, respective patterned implantation masks may be used to define selected areas exposed for the implantations, e.g., sub-collector region 14 and reach throughs 14a. The implantation mask used to select the exposed area for forming well is stripped after implantation, and before the implantation mask used to form the reach throughs 14a (or vice versa). The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The sub-collector region 14 and the reach throughs 14a may be doped with n-type dopants, e.g., Arsenic (As), Phosphorus (P) and Sb, among other suitable examples.

The base region 18 and the emitter region 20 may be formed by epitaxial growth processes, followed by a respective patterning process (e.g., lithography and etching). For example, the base region 18 may be formed by growing a polysilicon material and SiGe material on the semiconductor substrate 12. Following the growth process, the base region 18 is patterned to land on adjacent shallow trench isolation structures 18.

The emitter region 20 may be formed by depositing Si material on the base region 18. In embodiments, the deposition process may include an in-situ doping with an n-type dopant. The emitter region 20 may include sidewall spacers which may be formed by a deposition process of, e.g., nitride and/or oxide, followed by an anisotropic etching process. As shown, the emitter region 20 may be the highest feature of the vertical device, i.e., vertical bipolar junction transistor or vertical heterojunction bipolar junction transistor.

The shallow trench isolation structures 16 may be formed in the semiconductor substrate 12 by conventional lithography, etching and deposition methods known to those of skill in the art. For example, a resist formed over the semiconductor substrate 12 is exposed to energy (light) to form a pattern (opening). An etching process with a selective chemistry, e.g., reactive ion etching (RIE), will be used to transfer the pattern from the resist to the semiconductor substrate 12 to form one or more trenches in the semiconductor substrate 12 through the openings of the resist. Following the resist removal by a conventional oxygen ashing process or other known stripants, insulator material (e.g., oxide) can be deposited by any conventional deposition processes, e.g., chemical vapor deposition (CVD) processes. Any residual material on the surface of the semiconductor substrate 12 can be removed by conventional chemical mechanical polishing (CMP) processes.

In FIG. 3B, silicide contacts 25 are formed on exposed portions of semiconductor material, e.g., reach throughs 14a, base region 18 and emitter region 20. The silicide contacts 25 may be formed prior to the deposition of the interlevel dielectric material 24 and optional liner 22, using conventional silicide processes on exposed semiconductor material, e.g., exposed portions of the semiconductor substrate 12, base region 18 and emitter region 20. In an example, the silicide process begins with deposition of a thin transition metal layer, e.g., nickel, cobalt or titanium, over fully formed and patterned semiconductor devices (e.g., semiconductor substrate 12, base region 18 and emitter region 20). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 25.

In embodiments, an optional liner 22 may be formed over the exposed portions of the semiconductor substrate 12, a top surface of the shallow trench isolation structures 16, the base region 18, and the emitter region 20. In embodiments, the liner 22 may be a nitride material, for example, deposited by a blanket deposition method, e.g., CVD. An interlevel dielectric material 24 may be formed over the liner 22, in addition to over the base region 18 and the emitter region 20. In embodiments, the interlevel dielectric material 24 may be SiO₂ deposited by a CVD process. The interlevel dielectric material 24 may also be subjected to a planarization process, e.g., CMP.

Contacts 26 may be formed in the interlevel dielectric material 24 using a single damascene process, e.g., etching and deposition. In embodiments, the contacts 26 will contact the silicide contacts 25 of the semiconductor substrate 12, e.g., reach throughs 14a, and base region 18.

The contacts 26 can be formed by conventional lithography, etching and deposition methods known to those of skill in the art. For example, a resist formed over the interlevel dielectric material 24 is exposed to energy (light) to form a pattern (opening). An etching process with a selective chemistry, e.g., RIE, will be used to transfer the pattern to the interlevel dielectric material 24, forming one or more trenches in the interlevel dielectric material 24 that expose the underlying silicide contacts 25 for the base region 18 and the reach throughs 14a. Following the resist removal, conductive material can be deposited by any conventional deposition processes, e.g., chemical vapor deposition (CVD) processes. The conductive material may be tungsten, for example. Any residual material on the surface of the interlevel dielectric material 24 can be removed by conventional chemical mechanical polishing (CMP) processes.

As shown in FIG. 3C, one or more contacts 28 may be formed in the interlevel dielectric material 24, 24a extending to and contacting the silicide contacts 25 formed on the emitter region 20. The contacts 28 and wiring structures 32 may be formed by a dual damascene process, as an example.

For example, prior to forming of the contacts 28 and the wiring structures 32, an optional liner 30 may be formed over the interlevel dielectric material 24, with an additional interlevel dielectric material 24a formed over the liner 30. The liner 30 may be a nitride material and the interlevel dielectric material 24a may be SiO₂ as examples. The liner 30 and the interlevel dielectric material 24a may be deposited by conventional CVD processes.

The contacts 28 and the wiring structures 32 may be formed by lithography, etching and deposition processes, e.g., CVD, as is known in the art. In the case of an optional liner, for example, a nitride etch following an oxide etch may be required. An NFC (near frictionless carbon) may be used to fill in an open emitter contact hole during the oxide etch, and may be removed prior to the nitride etch so that the bottom of the liner 30 and the bottom of the emitter contact (through the liner 22) may be etched simultaneously. The contacts 28 may be formed by depositing a TaN liner followed by an electroplating process of copper, as an example. The wiring structures 32 may also be formed in a similar deposition process or same deposition process in case of a dual damascene process. A CMP process may be used to remove any additional material from the interlevel dielectric material 24a. Standard back end of the line (BEOL) process continue with upper wiring layers as is known in the art as shown in FIG. 1.

The emitter contacts 28 may have a top surface essentially coplanar with the top of the contacts 26. And as noted above, the contacts 28 comprise a different material than the material of the contacts 26

The bipolar junction transistor can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a collector region;
a base region adjacent to the collector region;
an emitter region adjacent to the base region;
contacts comprising a first material connecting to the collector region and the base region; and
at least one contact comprising a second material connecting to the emitter region.

2. The structure of claim 1, wherein the second material has a higher thermal conductivity than the first material.

3. The structure of claim 1, wherein the first material comprises tungsten and the second material comprises copper.

4. The structure of claim 1, wherein the collector region comprises reach throughs to a sub-collector region, and the contacts comprising the first material contact the reach throughs.

5. The structure of claim 1, wherein the base region is above the collector region and the emitter region is above the base region.

6. The structure of claim 5, wherein the at least one contact comprising the second material has a top surface coplanar with the contacts comprising the first material.

7. The structure of claim 5, wherein the at least one contact comprising the second material includes a liner of conductive material.

8. The structure of claim 5, further comprising wiring structures contacting the at least one contact and the contacts comprising the first material.

9. The structure of claim 8, wherein the wiring structures comprise the second material.

10. The structure of claim 9, wherein the at least one contact and the wiring structures connecting to the at least one contact are dual damascene structures.

11. The structure of claim 1, wherein the at least one contact is multiple contacts.

12. The structure of claim 1, wherein the at least one contact is wider than the contacts comprising the first material.

13. A structure comprising:
a collector region comprising a reach through and sub-collector;
a base region above the collector region;
an emitter region above the collector region;
contacts connecting to the collector region and the base region; and
at least one contact connecting to the emitter region and having a higher thermal conductivity than material of the contacts connecting to the collector region and the base region.

14. The structure of claim 13, wherein the material of the contacts comprises tungsten and the material of the at least one contact comprises copper.

15. The structure of claim 13, wherein the at least one contact comprises a top surface coplanar with the contacts.

16. The structure of claim 13, further comprising wiring structures contacting to the contacts and the at least one contact.

17. The structure of claim 16, wherein the wiring structures comprise a same material as the at least one contact.

18. The structure of claim 16, wherein the at least one contact and the wiring structures connecting to the at least one contact are dual damascene structures.

19. The structure of claim 13, wherein the at least one contact is of a different width than the contacts to the base region and the collector region.

20. A method comprising:
forming a collector region;
forming a base region adjacent to the collector region;
forming an emitter region adjacent to the base region;
forming contacts comprising a first material connecting to the collector region and the base region; and
forming at least one contact comprising a second material connecting to the emitter region.
